(19) United States
(12) Patent Application Publication
(10) Pub. No.: US 2026/0318961 A1
(43) Pub. Date: Oct. 15, 2026

(54) ELECTRIC MOTOR COMMON-MODE CURRENT MEASUREMENT AND CONTROL

(71) Applicant: GM Global Technology Operations LLC, Detroit, MI (US)

(72) Inventors: Anno Yoo, Rochester, MI (US); Suresh Gopalakrishnan, Troy, MI (US); Yilun Luo, Ann Arbor, MI (US); Chandra S. Namuduri, Troy, MI (US)

(21) Appl. No.: 19/176,516

(22) Filed: Apr. 11, 2025

(51) Int. Cl. G01R 19/165; G01R 15/20; G01R 19/10; G01R 31/00; G01R 31/34; H02P 21/22; H02P 21/24

(52) U.S. Cl. CPC G01R 19/16542; G01R 15/202; G01R 19/10; G01R 19/16547; G01R 31/006; G01R 31/343; H02P 21/22; H02P 21/24

(57) ABSTRACT

A method for controlling an alternating current (AC) motor for a vehicle may include measuring a first current in a first AC motor conductor. The method further may include measuring a second current in a second AC motor conductor. The method further may include determining a common-mode current in an AC system including an inverter and the AC motor. The method further may include determining a third current in a third AC motor conductor based at least in part on the first current, the second current, and the common-mode current. The method further may include determining the DC current based at least in part on the first current, the second current, and the third current.

### INTRODUCTION

The present disclosure relates to systems and methods for measuring the operating state and controlling alternating current (AC) motors in vehicle applications.

To regulate the operation of AC motors in vehicles, motor control systems may be utilized. Motor control systems may include a variety of sensors and control circuits configured to measure motor parameters such as current, voltage, rotational speed, and temperature. The data collected by these sensors may be processed by a motor controller to determine the motor's operating state and apply control algorithms to achieve desired performance. In some examples, the motor controller may employ vector control or field-oriented control (FOC) techniques to dynamically adjust motor current and voltage to achieve a desired motor torque and efficiency. Additionally, AC motor control systems may provide multi-phase control to drive motors in electric vehicle applications, enabling precise speed and torque regulation. Motor control systems may also incorporate fault detection mechanisms to identify and respond to abnormal operating conditions, such as overvoltage, overcurrent, or thermal overload conditions, ensuring reliable motor operation.

While systems and methods for AC motor control and measurement achieve their intended purpose, there is a need for new and improved systems and methods for controlling AC motors for vehicles.

### SUMMARY

According to several aspects, a method for determining a direct current (DC) current provided to an alternating current (AC) motor is provided. The method may include measuring a first current in a first AC motor conductor. The method further may include measuring a second current in a second AC motor conductor. The method further may include determining a common-mode current in an AC system including an inverter and the AC motor. The method further may include determining a third current in a third AC motor conductor based at least in part on the first current, the second current, and the common-mode current. The method further may include determining the DC current based at least in part on the first current, the second current, and the third current.

In another aspect of the present disclosure, determining the common-mode current further may include measuring a magnetic field induced in a common-mode choke in electromagnetic communication with two or more conductors of the AC system. Determining the common-mode current further may include determining the common-mode current based at least in part on the magnetic field.

In another aspect of the present disclosure, measuring the magnetic field induced in the common-mode choke further may include measuring the magnetic field induced in the common-mode choke. The common-mode choke is in electromagnetic communication with the first AC motor conductor, the second AC motor conductor, and the third AC motor conductor.

In another aspect of the present disclosure, measuring the magnetic field induced in the common-mode choke further may include measuring the magnetic field induced in the common-mode choke. The common-mode choke is in electromagnetic communication with a first DC conductor of the inverter and a second DC conductor of the inverter.

In another aspect of the present disclosure, measuring the magnetic field induced in the common-mode choke further may include measuring the magnetic field induced in the common-mode choke using a sensing coil electromagnetically coupled with the common-mode choke. A voltage induced across the sensing coil is proportional to a rate of change of the magnetic field.

In another aspect of the present disclosure, determining the common-mode current further may include measuring a voltage across a shunt resistance connected in parallel with the sensing coil. Determining the common-mode current further may include determining the common-mode current. The common-mode current is proportional to the voltage across the shunt resistance.

In another aspect of the present disclosure, determining the common-mode current further may include determining the common-mode current. The common-mode current is proportional to an integral of the voltage induced across the sensing coil over time.

In another aspect of the present disclosure, measuring the magnetic field induced in the common-mode choke further may include measuring the magnetic field induced in the common-mode choke using a point field detector in electromagnetic communication with the common-mode choke.

In another aspect of the present disclosure, determining the common-mode current further may include filtering the common-mode current using a low-pass filter to extract a fundamental motor speed dependent component of the common-mode current.

In another aspect of the present disclosure, determining the third current further may include determining the third current using a formula:

$${I}_{3} = - [ ( {I}_{1} ) + ( {I}_{2} ) + ( 3 * {I}_{CM} ) ]$$

where I₃ is the third current, I₁ is the first current, I₂ is the second current, and I_{CM} is the common-mode current.

According to several aspects, a system for controlling an alternating current (AC) motor for a vehicle is provided. The system may include an AC system including a plurality of conductors, the plurality of conductors including a first direct current (DC) conductor, a second DC conductor, a first AC motor conductor, a second AC motor conductor, and a third AC motor conductor, the AC system further includes an inverter in electrical communication with the first DC conductor and the second DC conductor. The system further may include the AC motor in electrical communication with inverter using the first AC motor conductor, the second AC motor conductor, and the third AC motor conductor. The system further may include a first current sensor configured to measure a first current in the first AC motor conductor. The system further may include a second current sensor configured to measure a second current in the second AC motor conductor. The system further may include a common-mode choke in electromagnetic communication with two or more of the plurality of conductors of the AC system. The system further may include a common-mode choke sensor configured to measure a magnetic field in the common-mode choke. The system further may include a controller in electrical communication with the first current sensor, the second current sensor, and the common-mode choke sensor. The controller is programmed to measure a first current in the first AC motor conductor using the first current sensor. The controller is further programmed to measure a second current in the second AC motor conductor using the second current sensor. The controller is further programmed to determine a common-mode current in the AC system using the common-mode choke sensor. The controller is further programmed to adjust an operation of the AC motor based at least in part on the common-mode current in the AC system.

In another aspect of the present disclosure, the common-mode choke is in electromagnetic communication with the first AC motor conductor, the second AC motor conductor, and the third AC motor conductor.

In another aspect of the present disclosure, the common-mode choke is in electromagnetic communication with the first DC conductor and the second DC conductor.

In another aspect of the present disclosure, the common-mode choke sensor includes a sensing coil electromagnetically coupled with the common-mode choke. A voltage induced across the sensing coil is proportional to a rate of change of the magnetic field.

In another aspect of the present disclosure, the common-mode choke sensor includes a point field detector in electromagnetic communication with the common-mode choke.

In another aspect of the present disclosure, to adjust the operation of the AC motor, the controller is further programmed to determine a third current in the third AC motor conductor using a formula:

$${I}_{3} = - [ ( {I}_{1} ) + ( {I}_{2} ) + ( 3 * {I}_{CM} ) ]$$

where I₃ is the third current, I₁ is the first current, I₂ is the second current, and I_{CM} is the common-mode current. To adjust the operation of the AC motor, the controller is further programmed to determine a torque provided by the AC motor based at least in part on the first current, the second current, and the third current. To adjust the operation of the AC motor, the controller is further programmed to adjust the operation of the AC motor based at least in part on the torque provided by the AC motor.

In another aspect of the present disclosure, to adjust the operation of the AC motor, the controller is further programmed to compare the common-mode current to a predetermined common-mode current threshold. To adjust the operation of the AC motor, the controller is further programmed to identify a fault in response to determining that the common-mode current is greater than the predetermined common-mode current threshold. To adjust the operation of the AC motor, the controller is further programmed to adjust the operation of the AC motor in response to identifying the fault.

According to several aspects, a method for controlling an alternating current (AC) motor for a vehicle is provided. The method may include measuring a first current in a first AC motor conductor. The method further may include measuring a second current in a second AC motor conductor. The method further may include measuring a magnetic field induced in a common-mode choke in electromagnetic communication with two or more conductors of an AC system including an inverter and the AC motor. The method further may include determining a common-mode current in the AC system based at least in part on the magnetic field. The method further may include adjusting an operation of the AC motor based at least in part on the common-mode current in the AC system.

In another aspect of the present disclosure, measuring the magnetic field induced in the common-mode choke and determining the common-mode current further may include measuring the magnetic field induced in the common-mode choke using a sensing coil electromagnetically coupled with the common-mode choke. A voltage induced across the sensing coil is proportional to a rate of change of the magnetic field. The common-mode choke is in electromagnetic communication with a first AC motor conductor, a second AC motor conductor, and a third AC motor conductor. Measuring the magnetic field induced in the common-mode choke and determining the common-mode current further may include determining the common-mode current. The common-mode current is proportional to an integral of the voltage induced across the sensing coil over time.

In another aspect of the present disclosure, adjusting the operation of the AC motor further may include comparing the common-mode current to a predetermined common-mode current threshold. Adjusting the operation of the AC motor further may include identifying a fault in response to determining that the common-mode current is greater than the predetermined common-mode current threshold. Adjusting the operation of the AC motor further may include adjusting the operation of the AC motor in response to identifying the fault. determining a third current in the third AC motor conductor using a formula:

$${I}_{3} = - [ ( {I}_{1} ) + ( {I}_{2} ) + ( 3 * {I}_{CM} ) ]$$

where I₃ is the third current, I₁ is the first current, I₂ is the second current, and I_{CM} is the common-mode current. Adjusting the operation of the AC motor further may include determining a torque provided by the AC motor based at least in part on the first current, the second current, and the third current. Adjusting the operation of the AC motor further may include adjusting the operation of the AC motor based at least in part on the torque provided by the AC motor.

Further areas of applicability will become apparent from the description provided herein. It should be understood that the description and specific examples are intended for purposes of illustration only and are not intended to limit the scope of the present disclosure.

### BRIEF DESCRIPTION OF THE DRAWINGS

The drawings described herein are for illustration purposes only and are not intended to limit the scope of the present disclosure in any way.

FIG. 1A is schematic diagram of a first exemplary embodiment of a system for controlling an alternating current (AC) motor for a vehicle, according to an exemplary embodiment;

FIG. 1B is schematic diagram of a second exemplary embodiment of a system for controlling an alternating current (AC) motor for a vehicle, according to an exemplary embodiment;

FIG. 2A is a schematic diagram of a first exemplary embodiment of a common-mode choke sensor, according to an exemplary embodiment;

FIG. 2B is a schematic diagram of a second exemplary embodiment of a common-mode choke sensor, according to an exemplary embodiment;

FIG. 2C is a schematic diagram of a third exemplary embodiment of a common-mode choke sensor, according to an exemplary embodiment; and

FIG. 3 is a flowchart of a method for controlling an AC motor for a vehicle, according to an exemplary embodiment.

### DETAILED DESCRIPTION

The following description is merely exemplary in nature and is not intended to limit the present disclosure, application, or uses.

In aspects of the present disclosure, it is advantageous to provide accurate control of alternating current (AC) motors for vehicles and other applications. In order to enable accurate control, it is advantageous to determine accurate data about the operating state of the motor (e.g., voltage, current, torque, etc.). Accordingly, the present disclosure provides a new and improved system and method for controlling an AC motor, including a method for determining a DC current provided to the AC motor, and more particularly, accounting for common-mode current provided to the AC motor.

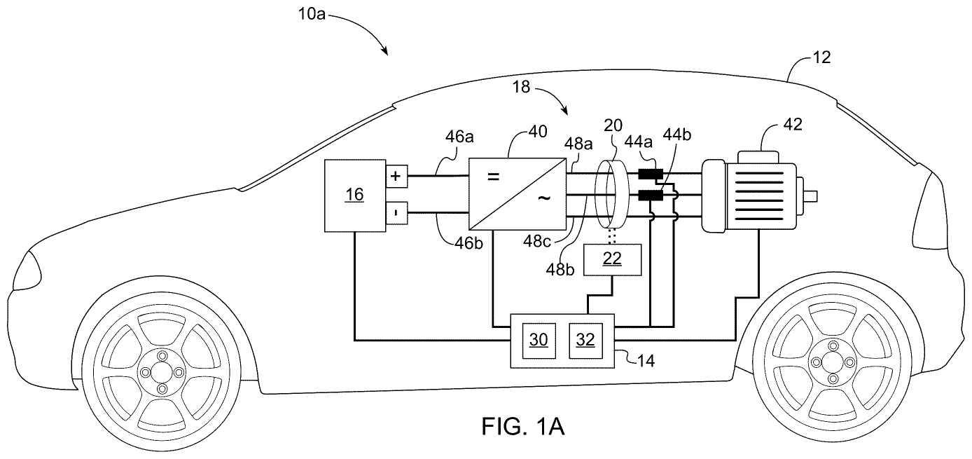

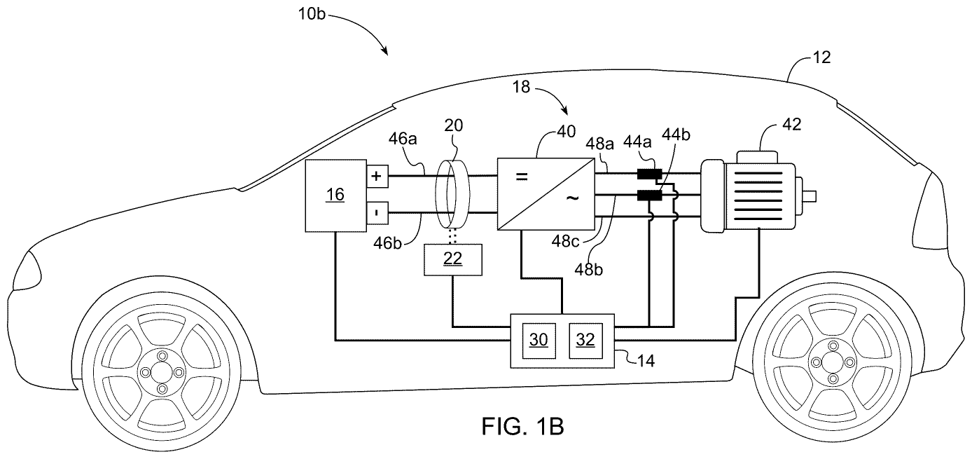

Referring to FIG. 1A, a first exemplary embodiment of a system for controlling an alternating current (AC) motor for a vehicle is illustrated and generally indicated by reference number 10a. The system 10a is shown with an exemplary vehicle 12. While a passenger vehicle is illustrated, it should be appreciated that the vehicle 12 may be any type of vehicle without departing from the scope of the present disclosure. The system 10a generally includes a controller 14, a rechargeable energy storage system (RESS) 16, an AC system 18, a common-mode choke 20, and a common-mode choke sensor 22.

The controller 14 is used to implement a method 100 for controlling an AC motor for a vehicle, as will be described below. The controller 14 includes at least one processor 30 and a non-transitory computer readable storage device or media 32. The processor 30 may be a custom made or commercially available processor, a central processing unit (CPU), a graphics processing unit (GPU), an auxiliary processor among several processors associated with the controller 14, a semiconductor-based microprocessor (in the form of a microchip or chip set), a macroprocessor, a combination thereof, or generally a device for executing instructions.

The computer readable storage device or media 32 may include volatile and nonvolatile storage in read-only memory (ROM), random-access memory (RAM), and keep-alive memory (KAM), for example. KAM is a persistent or non-volatile memory that may be used to store various operating variables while the processor 30 is powered down. The computer-readable storage device or media 32 may be implemented using a number of memory devices such as PROMs (programmable read-only memory), EPROMs (electrically PROM), EEPROMs (electrically erasable PROM), flash memory, or another electric, magnetic, optical, or combination memory devices capable of storing data, some of which represent executable instructions, used by the controller 14 to control various systems of the vehicle 12.

The controller 14 may also include multiple controllers which are in electrical communication with each other. The controller 14 may be inter-connected with additional systems and/or controllers of the vehicle 12, allowing the controller 14 to access data such as, for example, speed, acceleration, braking, and steering angle of the vehicle 12.

The controller 14 is in electrical communication with the RESS 16, the AC system 18, and the common-mode choke sensor 22. In an exemplary embodiment, the electrical communication is established using, for example, a CAN network, a FLEXRAY network, a local area network (e.g., WiFi, ethernet, and the like), a serial peripheral interface (SPI) network, or the like. It should be understood that various additional wired and wireless techniques and communication protocols for communicating with the controller 14 are within the scope of the present disclosure. It should further be understood that, in the scope of the present disclosure, electrical communication also includes power and/or energy transfer between electrical devices (e.g., using conducting wires and/or wireless power transmission techniques).

The RESS 16 stores and provides electrical energy in the form of direct current (DC) for operation of the vehicle 12. In an exemplary embodiment, the RESS 16 includes a plurality of battery cells (e.g., lithium-ion battery cells) electrically connected in series and/or parallel to provide an increased voltage and/or current-carrying capacity. In a non-limiting example, the plurality of battery cells are housed in an enclosure configured to protect the plurality of battery cells from mechanical vibration, water intrusion, and dust intrusion. The enclosure is also configured to provide temperature regulation (e.g., using a liquid cooling system, a resistive heating system, and/or the like). In an exemplary embodiment, the RESS 16 further includes a battery management system (BMS) configured to monitor battery characteristics such as a state of charge (SOC), state of health (SOH), temperature, and/or the like, and transmit the battery characteristics to the controller 14. In a non-limiting example, the BMS includes a BMS controller in electrical communication with a plurality of BMS sensors disposed within the enclosure of the RESS 16. In an exemplary embodiment, the RESS 16 provides a DC voltage across a positive and negative output terminal. The positive and negative output terminal are connected to the AC system 18 as will be discussed below.

The AC system 18 is used to propel the vehicle 12 by converting DC energy from the RESS 16 to mechanical energy. The AC system 18 includes an inverter 40, an AC motor 42, a first current sensor 44a, a second current sensor 44b, and a plurality of conductors. The inverter 40 is used to convert DC energy from the RESS 16 to three-phase AC energy for powering the AC motor 42. In an exemplary embodiment, the inverter 40 includes a plurality of power semiconductor devices, such as, for example, insulated-gate bipolar transistors (IGBTs), metal-oxide semiconductor field-effect transistors (MOSFETs), and/or the like configured to convert DC to three-phase AC. In a non-limiting example, the inverter 40 functions by switching the plurality of power semiconductor devices in a pattern to generate an AC sinusoidal output for each of the three phases. The pattern may be adjusted to vary an amplitude, frequency, and/or relative phase shift of each of the three phases in order to control speed, direction, and/or torque of the AC motor 42 based on signals from the controller 14.

The plurality of conductors includes a first DC conductor 46a and a second DC conductor 46b electrically connecting the inverter 40 to the RESS 16. The inverter 40 is in electrical communication with the controller 14, such that the controller 14 may enable, disable, and otherwise adjust the operation of the inverter 40. It should be understood that various types of inverters, including, for example, multi-level inverters, are within the scope of the present disclosure.

The AC motor 42 is used to convert electrical energy from the RESS 16 to mechanical energy (i.e., rotational energy) to propel the vehicle 12. In an exemplary embodiment, the AC motor 42 is a three-phase AC induction motor. In a non-limiting example, the AC motor 42 includes a stator having a plurality of stator windings and a rotor having a plurality of rotor windings disposed rotatably within the stator. The stator windings are excited by the three-phase AC provided by the inverter 40 to produce a rotating stator magnetic field. The rotating stator magnetic field induces currents in the rotor windings, which in turn produces a rotor magnetic field which interacts with the rotating stator magnetic field causing the rotor to rotate. The amplitude, frequency, and/or relative phase shift of the excitation of each of the three phases of the stator windings controls speed, direction, and/or torque of the AC motor 42. The plurality of conductors further includes a first AC motor conductor 48a, a second AC motor conductor 48b, and a third AC motor conductor 48c electrically connecting the inverter 40 to the AC motor 42.

The first current sensor 44a is used to measure current flowing through the first AC motor conductor 48a. In an exemplary embodiment, the first current sensor 44a is a Hall-effect sensor. In a non-limiting example, the Hall-effect sensor includes a Hall element and a signal conditioning circuit in electrical communication with the Hall element. The Hall element detects the magnetic field generated by the current flowing through the first AC motor conductor 48a, and the signal conditioning circuit processes the detected signal to determine the magnitude/direction of the current.

In another exemplary embodiment, the first current sensor 44a is a shunt resistor-based sensor. In a non-limiting example, the shunt resistor-based sensor includes a precision low-resistance shunt resistor and a differential amplifier in electrical communication with the shunt resistor. The shunt resistor is placed in series with the first AC motor conductor 48a, and the differential amplifier measures the voltage drop across the shunt resistor to calculate the current based on Ohm's law.

In yet another exemplary embodiment, the first current sensor 44a is a Rogowski coil. In a non-limiting example, the Rogowski coil includes a flexible air-core coil and an integrator circuit in electrical communication with the coil. The air-core coil encircles the first AC motor conductor 48a without direct electrical contact and induces a voltage proportional to the rate of change of the current. The integrator circuit processes this voltage to determine the actual current flowing through the first AC motor conductor 48a. It should be understood that the first current sensor 44a may be realized using any system, method, or device operable to measure current flowing in a conductor, including, for example, current transformers and the like. The first current sensor 44a is in electrical communication with the controller 14.

The second current sensor 44b is used to measure current flowing through the second AC motor conductor 48b. In an exemplary embodiment, the second current sensor 44b is a Hall-effect sensor. In a non-limiting example, the Hall-effect sensor includes a Hall element and a signal conditioning circuit in electrical communication with the Hall element. The Hall element detects the magnetic field generated by the current flowing through the second AC motor conductor 48b, and the signal conditioning circuit processes the detected signal to determine the magnitude/direction of the current.

In another exemplary embodiment, the second current sensor 44b is a shunt resistor-based sensor. In a non-limiting example, the shunt resistor-based sensor includes a precision low-resistance shunt resistor and a differential amplifier in electrical communication with the shunt resistor. The shunt resistor is placed in series with the second AC motor conductor 48b, and the differential amplifier measures the voltage drop across the shunt resistor to calculate the current based on Ohm's law.

In yet another exemplary embodiment, the second current sensor 44b is a Rogowski coil. In a non-limiting example, the Rogowski coil includes a flexible air-core coil and an integrator circuit in electrical communication with the coil. The air-core coil encircles the second AC motor conductor 48b without direct electrical contact and induces a voltage proportional to the rate of change of the current. The integrator circuit processes this voltage to determine the actual current flowing through the second AC motor conductor 48b. It should be understood that the second current sensor 44b may be realized using any system, method, or device operable to measure current flowing in a conductor, including, for example, current transformers and the like. The second current sensor 44b is in electrical communication with the controller 14.

The common-mode choke 20 is used to suppress common-mode current in two or more conductors. In an exemplary embodiment, the common-mode choke 20 is an electromagnetic component that provides high impedance to common-mode signals while allowing differential-mode signals to pass with minimal attenuation.

In an exemplary embodiment, the common-mode choke 20 includes a magnetic core in electromagnetic communication with the two or more conductors. In the scope of the present disclosure, electromagnetic communication refers to transfer of energy through electric and/or magnetic fields, for example, according to Ampere's law, Faraday's law of induction, and/or the like.

In a non-limiting example, the two or more conductors are wound around the magnetic core. The magnetic core is composed of a ferrite material that exhibits high permeability, thereby increasing the inductance for common-mode currents. The windings of the two or more conductors are arranged such that differential-mode currents induce opposing magnetic fields within the magnetic core which cancel each other, allowing the differential-mode current to pass. Common-mode currents induce additive magnetic fields within the magnetic core which results in attenuation of the common-mode signal.

In another non-limiting example, the common-mode choke 20 has a split-core design, where the magnetic core includes two separate core halves joined together. The split-core design allows for easy installation around the two or more conductors without requiring disconnection. The core halves may be composed of a high-permeability ferrite or nanocrystalline material, which enhances common-mode impedance across a wide frequency range. The two or more conductors may be wound onto each core half or passed through an aperture in the core. It should be understood that the examples of common-mode choke types discussed above are merely exemplary in nature, and that various additional and/or alternative types of common-mode chokes may be used within the scope of the present disclosure.

In the first exemplary embodiment of the system 10a, the common-mode choke 20 is in electromagnetic communication with the first AC motor conductor 48a, the second AC motor conductor 48b, and the third AC motor conductor 48c as shown in FIG. 1A. Referring to FIG. 1B, a second exemplary embodiment of a system for controlling an alternating current (AC) motor for a vehicle is illustrated and generally indicated by reference number 10b. The system 10b includes the same components as the system 10a. In the second exemplary embodiment of the system 10b, the common-mode choke 20 is in electromagnetic communication with the first DC conductor 46a and the second DC conductor 46b as shown in FIG. 1B. The remaining components of the system 10b are the same as the system 10a, and the description of the components provided above for the system 10a also applies to the system 10b.

It should be understood that the entire disclosure, including the method 100 as will be discussed below, is applicable to both system 10a (shown in FIG. 1A) and system 10b (shown in FIG. 1B). In other words, the common-mode choke 20 may be in electromagnetic communication with the first AC motor conductor 48a, the second AC motor conductor 48b, and the third AC motor conductor 48c OR the first DC conductor 46a and the second DC conductor 46b. Some embodiments may include two common-mode chokes, one in electromagnetic communication with the first AC motor conductor 48a, the second AC motor conductor 48b, and the third AC motor conductor 48c and another in electromagnetic communication with the first DC conductor 46a and the second DC conductor 46b.

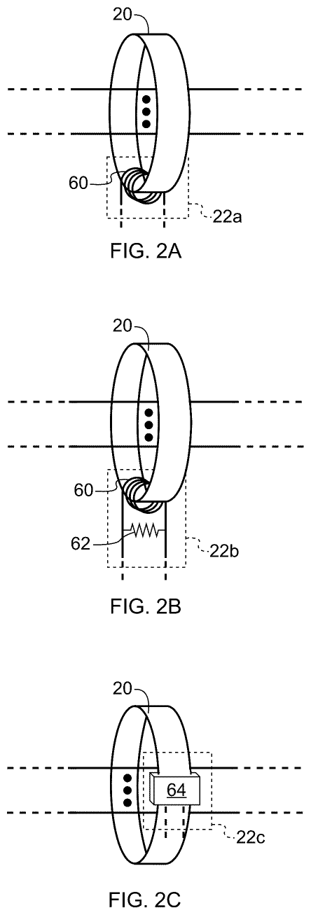

The common-mode choke sensor 22 is used to measure a magnetic field in the common-mode choke 20. The common-mode choke sensor 22 is an electronic or electromagnetic sensor operable to measure magnetic fields. Referring to FIG. 2A, the common-mode choke 20 is shown with a first exemplary embodiment 22a of the common-mode choke sensor 22. The first exemplary embodiment 22a of the common-mode choke sensor 22 includes a sensing coil 60 electromagnetically coupled with the common-mode choke 20. In the scope of the present disclosure, “electromagnetically coupled” means “in electromagnetic communication” as discussed above.

In a non-limiting example, the sensing coil 60 includes one or more turns of wire wrapped around the common-mode choke 20 (e.g., around the magnetic core of the common-mode choke 20) such that magnetic flux in the magnetic core of the common-mode choke 20 passes through a surface substantially perpendicular to a normal vector of the sensing coil 60. Therefore, according to Faraday's law of induction, a voltage induced across the sensing coil 60 is proportional to a rate of change of a magnetic field in the common-mode choke 20. Furthermore, the common-mode current in the conductors in electromagnetic communication with (e.g., enclosed by) the common-mode choke 20 is proportional to an integral of a voltage induced across the sensing coil 60 over time.

Referring to FIG. 2B, the common-mode choke 20 is shown with a second exemplary embodiment 22b of the common-mode choke sensor 22. The second exemplary embodiment 22b of the common-mode choke sensor 22 includes the sensing coil 60 electromagnetically coupled with the common-mode choke 20 and a shunt resistance 62 connected in parallel with the sensing coil 60. Therefore, the common-mode current in the conductors in electromagnetic communication with (e.g., enclosed by) the common-mode choke 20 is proportional to a voltage across the shunt resistance 62.

Referring to FIG. 2C, the common-mode choke 20 is shown with a third exemplary embodiment 22c of the common-mode choke sensor 22. The third exemplary embodiment 22c of the common-mode choke sensor 22 includes a point field detector 64 in electromagnetic communication with the common-mode choke 20. In the scope of the present disclosure, the point field detector 64 is a device operable to detect and measure magnetic fields at a specific point in space. In an exemplary embodiment, the point field detector 64 is disposed in a slit or gap of the magnetic core of the common-mode choke 20.

In an exemplary embodiment, the point field detector 64 is a Hall effect sensor. In a non-limiting example, the Hall-effect sensor includes a Hall element and a signal conditioning circuit in electrical communication with the Hall element. The Hall element detects the magnetic field within the magnetic core of the common-mode choke 20, and the signal conditioning circuit processes the detected signal to determine the magnitude/direction of the magnetic field. The common-mode current in the conductors in electromagnetic communication with (e.g., enclosed by) the common-mode choke 20 is proportional to the magnetic field within the magnetic core of the common-mode choke 20.

In another exemplary embodiment, the point field detector 64 is a magnetoresistive (MR) sensor. In a non-limiting example, the MR sensor includes a magnetoresistive element and a measurement circuit in electrical communication with the magnetoresistive element. The magnetoresistive element exhibits a change in electrical resistance in response to the magnetic field in the magnetic core of the common-mode choke 20, and the measurement circuit converts the resistance change into a signal indicating the magnitude/direction of the magnetic field. The common-mode current in the conductors in electromagnetic communication with (e.g., enclosed by) the common-mode choke 20 is proportional to the magnetic field within the magnetic core of the common-mode choke 20. It should be understood that the examples of point field detectors discussed above are merely exemplary in nature, and that various additional and/or alternative types of point field detectors may be used within the scope of the present disclosure.

It should be understood that the first exemplary embodiment 22a, the second exemplary embodiment 22b, and the third exemplary embodiment 22c of the common-mode choke sensor 22 discussed above are applicable to both embodiments 10a (FIG. 1A) and 10b (FIG. 1B), as discussed above. Furthermore, it should be understood that the exemplary embodiments of the common-mode choke sensor 22 discussed above are merely exemplary in nature, and that various additional and/or alternate types of common-mode choke sensors are within the scope of the present disclosure. Referring again to FIGS. 1A and 1B, the common-mode choke sensor 22 is in electrical communication with the controller 14.

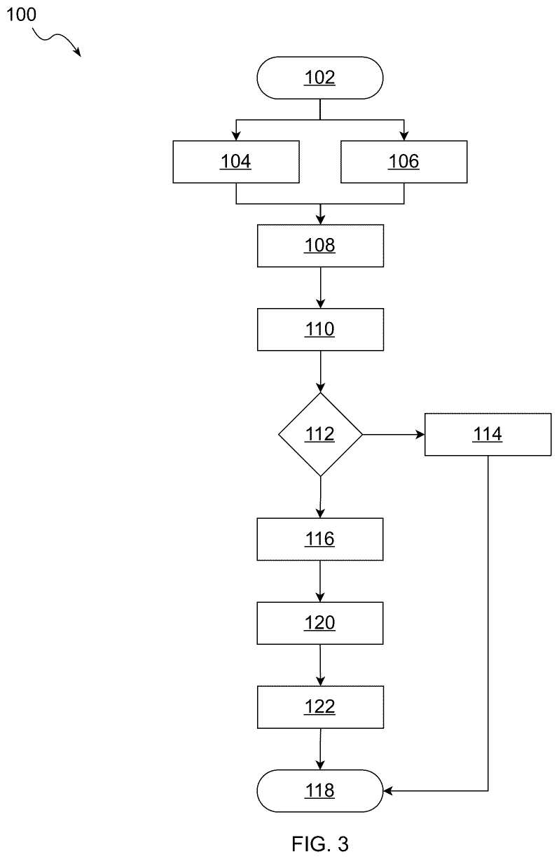

Referring to FIG. 3, a flowchart of the method 100 for controlling an AC motor for a vehicle is provided. The method 100 begins at block 102 and proceeds to blocks 104 and 106. At block 104, the controller 14 uses the first current sensor 44a to measure a first current in the first AC motor conductor 48a. After block 104, the method 100 proceeds to block 108, as will be discussed below. At block 106, the controller 14 uses the second current sensor 44b to measure a second current in the second AC motor conductor 48b. After block 106, the method 100 proceeds to block 108.

At block 108, the controller 14 uses the common-mode choke sensor 22 to measure a magnetic field induced in the common-mode choke 20. In an exemplary embodiment, the common-mode choke 20 is in electromagnetic communication with the first AC motor conductor 48a, the second AC motor conductor 48b, and the third AC motor conductor 48c as discussed above in reference to the system 10a (FIG. 1A). Therefore, the magnetic field is induced by common-mode current flowing in the first AC motor conductor 48a, the second AC motor conductor 48b, and the third AC motor conductor 48c. In another exemplary embodiment, the common-mode choke 20 is in electromagnetic communication with the first DC conductor 46a and the second DC conductor 46b as discussed above in reference to the system 10b (FIG. 1B). Therefore, the magnetic field is induced by common-mode current flowing in the first DC conductor 46a and the second DC conductor 46b.

It should be understood that the common-mode choke sensor 22 may include any of the first exemplary embodiment 22a of the common-mode choke sensor 22, the second exemplary embodiment 22b of the common-mode choke sensor 22, the third exemplary embodiment 22c of the common-mode choke sensor 22, and/or any other type of common-mode choke sensor, as discussed above. After block 108, the method 100 proceeds to block 110.

At block 110, the controller 14 determines the common-mode current in the conductors in electromagnetic communication with the common-mode choke 20 based at least in part on the magnetic field in the common-mode choke 20 measured at block 108. In an exemplary embodiment utilizing the first exemplary embodiment 22a of the common-mode choke sensor 22 discussed above, the common-mode current in the conductors in electromagnetic communication with the common-mode choke 20 is proportional to an integral of a voltage induced across the sensing coil 60 over time. In a non-limiting example, the controller 14 uses an analog-to-digital converter to measure the voltage induced across the sensing coil 60 over time and performs a numerical integration to calculate the common-mode current.

In another exemplary embodiment utilizing the second exemplary embodiment 22b of the common-mode choke sensor 22, the common-mode current in the conductors in electromagnetic communication with the common-mode choke 20 is proportional to a voltage across the shunt resistance 62. In a non-limiting example, the controller 14 uses the analog-to-digital converter to measure the voltage across the shunt resistance 62 to calculate the common-mode current. In another exemplary embodiment utilizing the third exemplary embodiment 22c of the common-mode choke sensor 22, the common-mode current in the conductors in electromagnetic communication with the common-mode choke 20 is proportional to the magnetic field within the magnetic core of the common-mode choke 20.

In general, the common-mode current is proportional to the magnetic field measured at block 108:

$${I}_{CM} = {k}_{c} * B \qquad ( 1 )$$

where I_{CM} is the common-mode current, B is the magnetic field, and k_{c} is a proportionality constant accounting for factors like the geometry of the magnetic core of the common-mode choke 20, material characteristics of the magnetic core, winding configuration of the conductors relative to the magnetic core, physical constants, and/or the like.

In an exemplary embodiment, at block 110, the controller 14 filters the common-mode current using a low-pass filter to extract a fundamental motor speed dependent component of the common-mode current. In the scope of the present disclosure, the fundamental motor speed dependent component of the common-mode current includes component(s) of the common-mode current which are dependent on the motor speed (i.e., rotational velocity) of the AC motor 42 and excludes extraneous components of the common-mode current attributable to noise. In a non-limiting example, the controller 14 uses digital signal processing to digitally filter the common-mode current. In another non-limiting example, the controller 14 uses an analog low-pass filter (integrated with the controller 14 or otherwise part of the system 10a, 10b) to filter the common-mode current. After block 110, the method 100 proceeds to block 112.

At block 112, the controller 14 compares the common-mode current determined at block 110 to a predetermined common-mode current threshold. The predetermined common-mode current threshold is a magnitude of common-mode current which indicates an isolation fault with the inverter 40 and/or the AC motor 42. If the common-mode current determined at block 110 is greater than the predetermined common-mode current threshold, the method 100 proceeds to block 114. If the common-mode current determined at block 110 is less than or equal to the predetermined common-mode current threshold, the method 100 proceeds to block 116.

At block 114, the controller 14 identifies a fault in response to determining that the common-mode current is greater than the predetermined common-mode current threshold. In an exemplary embodiment, the controller 14 adjusts the operation of the AC motor 42 in response to identifying the fault. In a non-limiting example, the controller 14 adjusts the operation of the AC motor 42 by de-energizing the AC motor 42 (e.g., by disabling the inverter 40 or by limiting/reducing an output power of the inverter 40) and providing a diagnostic warning to an occupant of the vehicle 12. After block 114, the method 100 proceeds to enter a standby state at block 118.

At block 116, the controller 14 determines a third current in the third AC motor conductor 48c based at least in part on the first current measured at block 104, the second current measured at block 106, and the common-mode current determined at block 110. Therefore, using the system 10a, 10b and the method 100, the third current is determined without the need for a third current sensor on the third AC motor conductor 48c. In an exemplary embodiment, the third current is determined using a formula:

$${I}_{3} = - [ ( {I}_{1} ) + ( {I}_{2} ) + ( 3 * {I}_{CM} ) ] \qquad ( 2 )$$

where I₃ is the third current, I₁ is the first current measured at block 104, I₂ is the second current measured at block 106, and I_{CM} is the common-mode current determined at block 110. In a non-limiting example, Equation 2 may include additional correction factors which correct for known measurement errors of the first current sensor 44a, the second current sensor 44b, and/or the common-mode choke sensor 22. After block 116, the method 100 proceeds to block 120.

At block 120, the controller 14 determines a direct current (DC) current provided to the AC motor 42 from the RESS 16 based at least in part on the first current measured at block 104, the second current measured at block 106, and the third current determined at block 116. In an exemplary embodiment, the DC current is an instantaneous value of the first current measured at block 104, the second current measured at block 106, and the third current determined at block 116. In another exemplary embodiment, the DC current from the RESS 16 is determined using a formula:

$${I}_{DC} = {S}_{1} {I}_{1} + {S}_{2} {I}_{2} + {S}_{3} {I}_{3} \qquad ( 3 )$$

where I_{DC} is the DC current, S₁ is a first switching function of the first AC motor conductor 48a, I₁ is the first current measured at block 104, S₂ is a second switching function of the second AC motor conductor 48b, I₂ is the second current measured at block 106, S₃ is a third switching function of the third AC motor conductor 48c, and I₃ is the third current determined at block 116.

In the scope of the present disclosure, the switching functions are related to the operation of the inverter 40. In a non-limiting example, the first switching function S₁ is related to a switching duty cycle on the first AC motor conductor 48a (i.e., a first AC phase of the inverter 40), the second switching function S₂ is related to a switching duty cycle on the second AC motor conductor 48b (i.e., a second AC phase of the inverter 40), and the third switching function S₃ is related to a switching duty cycle on the third AC motor conductor 48c (i.e., a third AC phase of the inverter 40). After block 120, the method 100 proceeds to block 122.

At block 122, the controller 14 adjusts the operation of the AC motor 42 based at least in part on the DC current determined at block 120. In an exemplary embodiment, the controller 14 determines a torque provided by the AC motor 42 based at least in part on the DC current determined at block 120. In a non-limiting example, the torque provided by the AC motor 42 is proportional to the DC current:

$$T = \frac{{V}_{DC} * {I}_{DC} - {L}_{I} - {L}_{M}}{{W}_{rm}} \qquad ( 4 )$$

where T is the torque provided by the AC motor 42, V_{DC} is a voltage of the RESS 16 or a DC-link voltage of the inverter 40, I_{DC} is the DC current determined at block 120, L_{I} is a power loss of the inverter 40, L_{M} is a power loss of the AC motor 42, and Wᵣₘ is a rotational velocity of the AC motor 42. It should be understood that other relationships between torque and DC current are within the scope of the present disclosure.

In an exemplary embodiment, the controller 14 adjusts the operation of the AC motor 42 based at least in part on the torque provided by the AC motor 42. In a non-limiting example, the controller 14 executes a closed-loop control algorithm to adjust the voltage, current, frequency, phase angle, etc. of the output of the inverter 40 to the AC motor 42 based at least in part on the torque provided by the AC motor 42. For example, the controller 14 may execute a closed-loop control algorithm configured to maintain the torque provided by the AC motor 42 at a given setpoint. It should be understood that various additional and/or alternate control actions based on the torque provided by the AC motor 42 are within the scope of the present disclosure, including, for example, diagnostic actions, data gathering/crowdsourcing actions, information display actions (e.g., providing information about the torque provided by the AC motor 42 to the occupant of the vehicle 12), and/or the like. After block 122, the method 100 proceeds to enter the standby state at block 118.

In an exemplary embodiment, the controller 14 repeatedly exits the standby state 118 and restarts the method 100 at block 102. In a non-limiting example, the controller 14 exits the standby state 118 and restarts the method 100 on a timer, for example, every three hundred milliseconds.

The system 10a, 10b and method 100 of the present disclosure offer several advantages. Using the system 10a, 10b and the method 100, the third current in the third AC motor conductor 48c is determined without the need for a third current sensor, decreasing weight, resource use, and component count. Furthermore, the effect of the common-mode current is accounted for when determining the third current, increasing the accuracy of the current determination and thus allowing for more accurate control of the AC motor 42. Additionally, identification of isolation faults and other diagnostic tasks may be performed to control the AC motor 42 based on the common-mode current as determined using the system 10a, 10b and the method 100.

The description of the present disclosure is merely exemplary in nature and variations that do not depart from the gist of the present disclosure are intended to be within the scope of the present disclosure. Such variations are not to be regarded as a departure from the spirit and scope of the present disclosure.

What is claimed is:

1. A method for determining a direct current (DC) current provided to an alternating current (AC) motor, the method comprising:
measuring a first current in a first AC motor conductor;
measuring a second current in a second AC motor conductor;
determining a common-mode current in an AC system including an inverter and the AC motor;
determining a third current in a third AC motor conductor based at least in part on the first current, the second current, and the common-mode current; and
determining the DC current based at least in part on the first current, the second current, and the third current.

2. The method of claim 1, wherein determining the common-mode current further comprises:
measuring a magnetic field induced in a common-mode choke in electromagnetic communication with two or more conductors of the AC system; and
determining the common-mode current based at least in part on the magnetic field.

3. The method of claim 2, wherein measuring the magnetic field induced in the common-mode choke further comprises:
measuring the magnetic field induced in the common-mode choke, wherein the common-mode choke is in electromagnetic communication with the first AC motor conductor, the second AC motor conductor, and the third AC motor conductor.

4. The method of claim 2, wherein measuring the magnetic field induced in the common-mode choke further comprises:
measuring the magnetic field induced in the common-mode choke, wherein the common-mode choke is in electromagnetic communication with a first DC conductor of the inverter and a second DC conductor of the inverter.

5. The method of claim 2, wherein measuring the magnetic field induced in the common-mode choke further comprises:
measuring the magnetic field induced in the common-mode choke using a sensing coil electromagnetically coupled with the common-mode choke, wherein a voltage induced across the sensing coil is proportional to a rate of change of the magnetic field.

6. The method of claim 5, wherein determining the common-mode current further comprises:
measuring a voltage across a shunt resistance connected in parallel with the sensing coil; and
determining the common-mode current, wherein the common-mode current is proportional to the voltage across the shunt resistance.

7. The method of claim 5, wherein determining the common-mode current further comprises:
determining the common-mode current, wherein the common-mode current is proportional to an integral of the voltage induced across the sensing coil over time.

8. The method of claim 2, wherein measuring the magnetic field induced in the common-mode choke further comprises:
measuring the magnetic field induced in the common-mode choke using a point field detector in electromagnetic communication with the common-mode choke.

9. The method of claim 2, wherein determining the common-mode current further comprises:
filtering the common-mode current using a low-pass filter to extract a fundamental motor speed dependent component of the common-mode current.

10. The method of claim 1, wherein determining the third current further comprises:
determining the third current using a formula:
$${I}_{3} = - [ ( {I}_{1} ) + ( {I}_{2} ) + ( 3 * {I}_{CM} ) ]$$
wherein I₃ is the third current, I₁ is the first current, I₂ is the second current, and I_{CM} is the common-mode current.

11. A system for controlling an alternating current (AC) motor for a vehicle, the system comprising:
an AC system including a plurality of conductors, the plurality of conductors including a first direct current (DC) conductor, a second DC conductor, a first AC motor conductor, a second AC motor conductor, and a third AC motor conductor, the AC system further comprising:
an inverter in electrical communication with the first DC conductor and the second DC conductor; and
the AC motor in electrical communication with inverter using the first AC motor conductor, the second AC motor conductor, and the third AC motor conductor;
a first current sensor configured to measure a first current in the first AC motor conductor; and
a second current sensor configured to measure a second current in the second AC motor conductor;
a common-mode choke in electromagnetic communication with two or more of the plurality of conductors of the AC system;
a common-mode choke sensor configured to measure a magnetic field in the common-mode choke; and
a controller in electrical communication with the first current sensor, the second current sensor, and the common-mode choke sensor, wherein the controller is programmed to:
measure a first current in the first AC motor conductor using the first current sensor;
measure a second current in the second AC motor conductor using the second current sensor;
determine a common-mode current in the AC system using the common-mode choke sensor; and
adjust an operation of the AC motor based at least in part on the common-mode current in the AC system.

12. The system of claim 11, wherein the common-mode choke is in electromagnetic communication with the first AC motor conductor, the second AC motor conductor, and the third AC motor conductor.

13. The system of claim 11, wherein the common-mode choke is in electromagnetic communication with the first DC conductor and the second DC conductor.

14. The system of claim 11, wherein the common-mode choke sensor includes a sensing coil electromagnetically coupled with the common-mode choke, wherein a voltage induced across the sensing coil is proportional to a rate of change of the magnetic field.

15. The system of claim 11, wherein the common-mode choke sensor includes a point field detector in electromagnetic communication with the common-mode choke.

16. The system of claim 11, wherein to adjust the operation of the AC motor, the controller is further programmed to:
determine a third current in the third AC motor conductor using a formula:
$${I}_{3} = - [ ( {I}_{1} ) + ( {I}_{2} ) + ( 3 * {I}_{CM} ) ]$$
wherein I₃ is the third current, I₁ is the first current, I₂ is the second current, and I_{CM} is the common-mode current;
determine a torque provided by the AC motor based at least in part on the first current, the second current, and the third current; and
adjust the operation of the AC motor based at least in part on the torque provided by the AC motor.

17. The system of claim 11, wherein to adjust the operation of the AC motor, the controller is further programmed to:
compare the common-mode current to a predetermined common-mode current threshold;
identify a fault in response to determining that the common-mode current is greater than the predetermined common-mode current threshold; and
adjust the operation of the AC motor in response to identifying the fault.

18. A method for controlling an alternating current (AC) motor for a vehicle, the method comprising:
measuring a first current in a first AC motor conductor;
measuring a second current in a second AC motor conductor;
measuring a magnetic field induced in a common-mode choke in electromagnetic communication with two or more conductors of an AC system including an inverter and the AC motor;
determining a common-mode current in the AC system based at least in part on the magnetic field; and
adjusting an operation of the AC motor based at least in part on the common-mode current in the AC system.

19. The method of claim 18, wherein measuring the magnetic field induced in the common-mode choke and determining the common-mode current further comprises:
measuring the magnetic field induced in the common-mode choke using a sensing coil electromagnetically coupled with the common-mode choke, wherein a voltage induced across the sensing coil is proportional to a rate of change of the magnetic field, and wherein the common-mode choke is in electromagnetic communication with a first AC motor conductor, a second AC motor conductor, and a third AC motor conductor; and
determining the common-mode current, wherein the common-mode current is proportional to an integral of the voltage induced across the sensing coil over time.

20. The method of claim 19, wherein adjusting the operation of the AC motor further comprises:
comparing the common-mode current to a predetermined common-mode current threshold;
identifying a fault in response to determining that the common-mode current is greater than the predetermined common-mode current threshold; and
adjusting the operation of the AC motor in response to identifying the fault;
determining a third current in the third AC motor conductor using a formula:
$${I}_{3} = - [ ( {I}_{1} ) + ( {I}_{2} ) + ( 3 * {I}_{CM} ) ]$$
wherein I₃ is the third current, I₁ is the first current, I₂ is the second current, and I_{CM} is the common-mode current;
determining a torque provided by the AC motor based at least in part on the first current, the second current, and the third current; and
adjusting the operation of the AC motor based at least in part on the torque provided by the AC motor.
